(19) United States
(12) Patent Application Publication
(10) Pub. No.: US 2009/0181545 A1
(43) Pub. Date: Jul. 16, 2009

(54) DRY-ETCHING METHOD AND APPARATUS

(76) Inventors: Nobuyuki Negishi, Kodaira (JP); Masaru Izawa, Hino (JP); Masatsugu Arai, Chiyoda (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/400,697

(22) Filed: Mar. 9, 2009

Related U.S. Application Data
(62) Division of application No. 11/067,700, filed on Mar. 1, 2005.

(30) Foreign Application Priority Data
Jun. 23, 2004 (JP) 2004-184402
Feb. 7, 2005 (JP) 2005-030682

(51) Int. Cl. H01L 21/3065

(52) U.S. Cl. 438/710; 257/E21.218

(57) ABSTRACT

A resist damage free dry-etching process is proposed. A time duration defined until bias electric power is applied is controlled according to a plasma ignition detection signal. Wafer back-side gas pressure for a certain constant time after starting of an etching process operation is set to be lower than that as to a main etching condition. Within the time duration defined after starting of the etching process operation up to a certain constant time, CₓF_{y} gas having a lower C/F ratio than that of the main etching condition is employed, or a flow rate of the CₓF_{y} gas is lowered. The above-described parameter values are controlled every wafer according to an amount of radicals contained in the plasma being monitored. A unit for preheating a wafer is installed in a wafer transporting system.

### CROSS-REFERENCE TO RELATED APPLICATIONS

This application is a divisional of U.S. application Ser. No. 11/067,700, filed Mar. 1, 2005, and which application claims priority from Japanese patent applications No. 2004-184402, filed Jun. 23, 2004 and No. 2005-030682, filed Feb. 7, 2005, the contents of which are hereby incorporated by reference into this application.

### BACKGROUND OF THE INVENTION

The present invention generally relates to a dry-etching apparatus and a dry-etching method, which are especially used in etching process operations for etching interlayer insulating films among etching process steps. More specifically, the present invention is directed to a method capable of reducing resist damage occurred in forming of vias, forming of high aspect ratio contacts, forming of self-alignment contacts, forming of trenches, forming of damascenes, forming of gate masks, and the like, while employing resist patterns subsequent to an ArF lithography generation.

In a semiconductor device, in order to electrically connect transistors to metal wiring lines, and electrically connect these metal wiring lines to each other, which have been formed on a wafer, contact holes are formed in interlayer insulating films formed between upper portions of transistor structures and the metal wiring lines by a dry-etching method using plasma, and then, either semiconductors or metals are filled into the contact holes. More specifically, in a high integration/high speed logic device manufacturing method subsequent to a 90 nm node, a damascene step and an ArF lithography have been utilized. In the damascene step, trenches and vias are formed in interlayer insulating films by way of a dry-etching method, and then, Cu(copper) is embedded in these trenches and vias as wiring materials, while these interlayer insulating films correspond to a Low-k material having a low dielectric constant. In the ArF lithography, a light source of 193 nm is employed so as to form very fine patterns. A dry etching method corresponds to such an etching technique that etching gas conducted into vacuum chambers is converted into plasma by using high frequency electric power which is external applied, and then, since reactive radicals and ions which are produced in the plasma are reacted on wafers in high precision, films to be processed are selectively etched with respect to mask materials which are typically known as resists, wiring layers and underlayer substrates which are located under vias and contact holes.

Normally, when wiring patterns of semiconductor circuits are formed, organic-film-series reflection preventing films (BARC) are formed on films to be processed, and furthermore, resist films are formed thereon. The BARC is employed in order to avoid forming of abnormal patterns, which is caused by interference of laser light, while this laser light corresponds to a light source of a lithography. After the resist patterns have been formed, etching process operation for the BARC is carried out. Thereafter, etching process operation for the films to be processed is carried out (namely, main etching process operation). In the etching process operation for the BARC, such an etching process operation is performed. That is, since the material of this BARC is C rich similar to the resist, F rich fluorocarbon (e.g., CF₄, CHF₃ etc.) and mixed gas are conducted; plasma is produced in such a pressure range from 0.5 Pa to 10 Pa; and then, the etching process operation for the BARC is carried out by controlling energy of ions entered into a wafer within a pressure range defined from 0.1 KV to 1.0 KV. The mixed gas is made of oxygen gas and rare gas which is typically known as Ar (argon).

Also, when vias and contact holes are formed, fluorocarbon gas (CF₄, CHF₃, C₂F₆, C₃F₆O, C₄F₈, C₅F₈, C₄F₆ etc.) and mixed gas are conducted as plasma gas; plasma is produced in such a pressure range from 0.5 Pa to 10 Pa; and energy of ions which are entered into the wafer is accelerated from 0.5 KV up to 2.5 KV.

In these etching process operations, after the plasma had been ignited, the ignited plasma has been sufficiently grown, and thereafter, the bias electric power has been applied to the wafer. In such an assuming case that the bias electric power is applied under condition that the plasma has not yet been sufficiently grown, or under such a condition that the plasma is not yet ignited, depending upon the plasma condition, currents flowing into the plasma cannot be sufficiently secured, or none of current flows into the plasma. As a result, extraordinary high voltages may be applied to bias electric power supplying lines, electrodes for setting thereon the wafers. As a consequence, there are some possibilities that dielectric breakdown may occur in the bias electric power supplying lines, spraying films on the electrodes may be broken, or the wafers may be cracked. Under such a circumstance, in view of mass production, while means for detecting ignitions of plasma is normally provided, for instance, a monitor for monitoring emission intensity of plasma is provided, bias electric power has been applied to wafers after a constant time duration has elapsed since the ignitions of plasma were detected. Also, while gas conditions (gas kinds and gas flow rates) and gas pressure as to wafer back-side for cooling wafers are basically kept as the same conditions from commencements of etching process operations until completions of these etching process operations, the process operations have been carried out.

### SUMMARY OF THE INVENTION

In the above-explained etching steps, the resist materials subsequent to the ArF lithography may owns the following problems. That is, resist etching rate of these resist materials is high, and roughness of surfaces thereof which are caused by resist damage are large, as compared with those of conventional KrF resists and conventional i-line resists.

In these KrF resists, etching durabilitys thereof are sufficiently larger than those of these ArF resists, and also, integration degrees of devices are not so high. As a consequence, striation and line edge roughness do not constitute a serious problem in these KrF resists. However, more specifically, in such etching process operations which require higher dimensional precision, e.g., in an SiN mask etching process operation which is employed as an element separation forming-purpose mask, and in a hard mask etching process operation which is typically known as SiO₂ used to form a gate electrode, deteriorations of line edge roughness which are caused by coarse resists after being etched may give large influences to device characteristics. Also, in etching process operations of Low-k materials (SiOC films) corresponding to interlayer insulating films which are presently conducted into manufacturing of high integration logic devices, ions having high energy are irradiated by applying relatively high bias electric power, and also, etching process operations are carried out in O₂ rich gas atmospheres. As a result, a resist punching-through phenomenon may occur in which holes are locally pierced in positions where no pattern is formed in addition to an occurrence of striation on side walls of patterns.

As a consequence, an object of the present invention is to provide both an etching method capable of securing etching durability of a resist subsequent to the ArF lithography generation, and an etching apparatus capable of realizing the above-described etching method in an etching process operation where the above-explained resist subsequent to the ArF lithography generation is employed as a mask.

With application of either one of the following measures, the present invention can reduce carbon deposited on a wafer in an initial stage of an etching process operation, as compared with that of the prior art, so as to secure an etching durability of a resist.

According to a first solution, in such an etching process operation with employment of a resist material having a lower etching durability (ArF resist etc.), as compared as the conventional resist material, a time duration is controlled which is defined after plasma has been ignited until bias electric power is applied to a wafer in either etching of an organic-film-series reflection preventing film or etching of a layer to be processed. Preferably, this time duration may be controlled within 1 second.

According to a second solution, as a gas condition from a commencement of an etching process operation until a wafer temperature is saturated to a constant value, gas having a lower C/F ratio than that of an actual etching condition is employed, or CₓF_{y} gas having a low flow rate is employed.

According to a third solution, for a constant time period after an etching process operation is commenced, gas pressure of back-side of a wafer in an actual etching process operation is set to be low gas pressure.

According to fourth solution, a temperature of a wafer is increased to a desirable temperature until the wafer is transported to a vacuum chamber.

According to a fifth solution, while an amount of radicals contained in plasma is measured, timing for applying bias electric power, a gas condition and wafer back-side gas pressure for an initial stage of an etching process operation, are controlled based upon the measured radical amount.

According to a sixth solution, since a surface temperature of a wafer is directly, or indirectly monitored from an opposite direction, or an oblique direction with respect to the wafer, or from the back-side of the wafer, the above-described control operation is carried out in high precision.

According to a seventh solution, an etching time dependent characteristic as to a wafer surface temperature based upon a process condition is previously predicted by executing a calculation, and then, both the gas pressure as to the wafer back-side and time thereof are set in either a manual manner or an automatic manner in such a way that this predicted etching time dependent characteristic may become a desirable profile, so that an etching process operation can be carried out in high precision.

In accordance with the present invention, resist damage can be effectively suppressed which may constitute the problem occurred when the patterns are formed while the resist having the low etching durability subsequent to the ArF lithography is employed, and also, the resist punching-through phenomenon and the striation can be improved which are caused by the resist damage. Also, since the radicals contained in the plasma are monitored, the control operation can be carried out in conjunction with the etching atmosphere, and this radical monitoring operation may also contribute an improvement in a long-term stability.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for graphically representing a relationship between a surface temperature of a wafer and a time duration after bias electric power has been applied to the wafer.

FIG. 2A to FIG. 2D are conceptional diagrams for explaining resist damage which is caused by a thickness of a CF polymer deposited on a resist.

FIG. 3A to FIG. 3C are etching sequence diagrams obtained while an attention is paid to plasma electric power, bias electric power, and helium pressure of a back-side of a wafer.

FIG. 4 is a diagram for graphically showing a relationship between helium pressure of the back-side and a surface temperature of a wafer.

FIG. 5A to FIG. 5C indicate scanning electron microscopic photographs which represent etching shapes of trenches and holes in various kinds of sequences.

FIG. 6A and FIG. 6B are scanning electron microscopic photographs for showing etching shapes of trench patterns made by conducting a low deposition steps, or not when an etching process operation is commenced.

FIG. 7 is a diagram for graphically showing a relationship between a thickness of a CF deposited film and a C/F ratio of fluorocarbon under steady-state etching condition.

FIG. 8 is a diagram for graphically representing a relationship between a time duration defined after discharging operation has been commenced and a ratio of emission intensity (C₂/O ratio).

FIG. 9 is a schematic diagram for showing an etching apparatus in order to realize Embodiment 2 of the present invention.

FIG. 10 is a schematic diagram for showing an etching system in order to realize Embodiment 2 of the present invention.

FIG. 11 is a schematic diagram for indicating an electrode in order to realize Embodiment 5 of the present invention.

FIG. 12A to FIG. 12 C are scanning electron microscopic photographs for representing etching shapes of holes made by controlling helium pressure of a wafer back-side in Embodiment 5 of the present invention.

FIG. 13 is a schematic diagram for explaining such a case that a radiation thermometer is installed in a dielectric substance portion in Embodiment 1 of the present invention.

FIG. 14 is a schematic diagram for representing such a case that a surface temperature of a wafer is monitored from a back-side of a silicon disk by employing the radiation thermometer in Embodiment 1 of the present invention.

FIG. 15 is a schematic diagram for showing a preheating operation with employment of a heater according to Embodiment 3 of the present invention.

FIG. 16 is a schematic diagram for showing a preheating operation with employment of a lamp according to Embodiment 3 of the present invention.

### DETAILED DESCRIPTION OF THE EMBODIMENTS

Before describing various embodiments of the present invention, an explanation is made of an approach in order to suppress an excessive deposition in accordance with the present invention.

In etching process operations executed while resists subsequent to the ArF lithography generation are employed as masks, means capable of suppressing resist damage are different from each other, depending upon a BARC (organic-film-series reflection preventing film) process operation and a main etching operation, for example, forming of a contact. Concrete suppressing means have been described in Japanese Patent Application No. 2003-303961. In this description, in a BARC process operation executed under such an etching condition with a small amount of depositions, it is important to reduce ion sputtering components. In order to reduce the ion sputtering components, a flow rate of Ar (argon) which is employed as dilution gas is set to be smaller than, or equal to 10% (preferably 0%) with respect to an entire plasma gas flow rate. As a result, a surface of the resist after the BARC process operation has been carried out may become smooth, and a degree of resist damage under the main etching condition (for example, contact processing operation) which is subsequently executed can be suppressed.

On the other hand, in a contact processing operation with a large amount of depositions, in order to suppress dissociation occurred in plasma, the plasma is diluted by using either Xe (xenon) gas or kr (krypton) gas, the ionizing energy of which is small. Otherwise, it is effective to add either Xe gas or Kr gas to Ar (argon) gas which is normally used as dilution gas. In other words, if a quality of a deposited film (namely, F/C ratio measured by XPS) during an etching process operation becomes F rich, or an amount of depositions itself becomes small, then resist damage can be suppressed. Note that symbol “XPS” implies an X-ray photoelectron spectroscopy.

In accordance with the present invention, while these results are considered, a means capable of further suppressing the resist damage may be provided.

A thickness of a deposited film under such a condition that a temperature of a wafer is low in an initial stage of an etching process operation becomes thick, as compared with that of the normal etching condition under which the temperature of the wafer has been increased. In order to suppress this excessive deposition, three different approaches may be mainly conceived.

In a first approach, such a time duration must be shortened as being permitted as possible, while this time duration is defined after plasma is ignited until bias electric power required so as to accelerate ions is applied. However, if the bias electric power is applied at a time instant when plasma is insufficiently grown, then a current flowing into a wafer cannot be sufficiently secured, but also, an extraordinarily higher voltage is applied to a transmission line of the bias electric power, an electrode, and the wafer, as compared with a voltage under the normal condition. As a result, there are some risks that insulating breakdowns of the respective portions occur, and the wafer is cracked. As a consequence, it is important that while an ignition of plasma is monitored, timing for applying bias electric power is controlled in response to the monitored value.

In a second approach, an etching step of a low deposition condition is inserted into a stage when an etching process operation is commenced. Concretely speaking, a gas kind having a lower C/F ratio is employed, as compared with that of CₓF_{y} gas which is employed in a main etching condition. As represented in FIG. 7, in connection with such a condition that a C/F ratio of fluorocarbon gas (CₓF_{y}) is decreased, a deposition amount is reduced. As a consequence, since gas having a low C/F ratio is employed when an etching process operation is commenced (namely, present condition is not yet brought into normal etching condition), a CF polymer deposited on a wafer can be suppressed for such a time duration that a temperature of the wafer becomes the normal condition. Thereafter, the present etching process operation is advanced to an actual main etching condition, so that resist damage can be suppressed while no adverse influence is given to etching performance. Also, as a means capable of achieving a similar effect, there is a control of a CₓF_{y} gas flow rate. Since a gas flow rate when an etching process operation is commenced is made smaller than a gas flow amount of an actual etching condition, an excessive deposition occurred when the etching process operation is commenced can be suppressed.

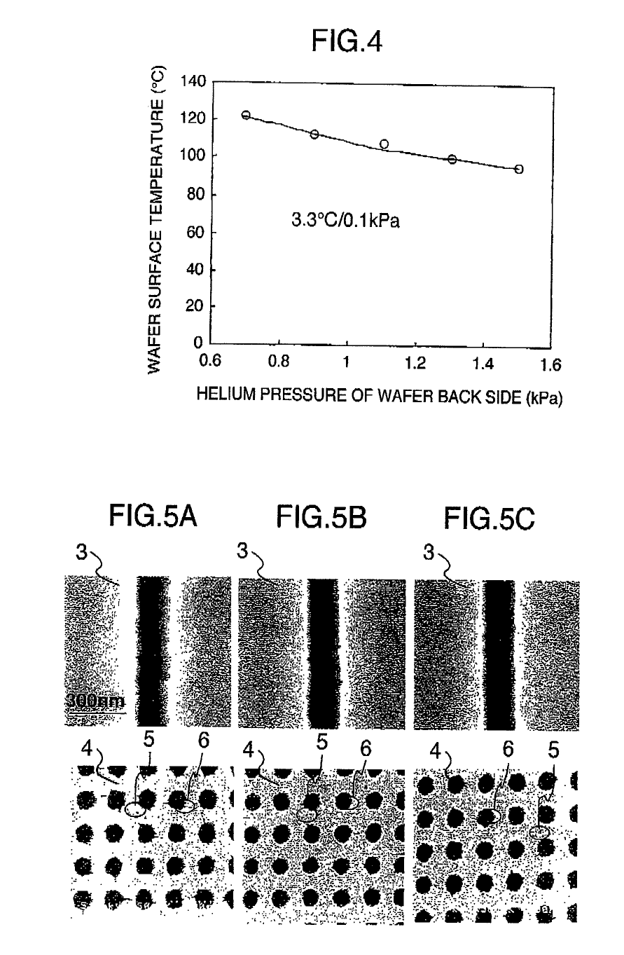

In a third approach, when an etching process operation is commenced, a step of lower pressure than gas pressure of a wafer back-side under an actual etching condition is conducted. As a result, a temperature of a wafer in an initial stage of an etching process operation can be increased. Normally, in order to control a temperature of the wafer, refrigerant such as Fluorinert (trademark of 3M) is supplied to an internal portion of an electrode where the wafer is set, and helium gas having high heat conduction is filled into a space between the wafer and the electrode, so that a thermal contact may be improved. In the case that a temperature of refrigerant is controlled to a certain set value and bias electric power is applied to a wafer, a temperature of this wafer may be exclusively determined based upon pressure of the wafer back-side helium gas (see FIG. 4).

Also, it is effective to control these means based upon a monitored value of radical amounts contained in plasma. In the case that plural sheets of wafers are processed in a mass production field, since polymers of a CF series which are deposited on a wall are increased in conjunction with quantities of processed wafers, radicals of the CF series are radiated from the wall in conjunction with the quantities of processed wafers. In accordance with the radiation of these radicals, the polymers of the CF series are gradually deposited on the wafer. Thus, there is a risk that resist damage may occur. However, for instance, while emission intensity of “C₂” is monitored, gas conditions (gas flow rate and gas kind) and step time in the step which is conducted to the initial stage of the etching process operation are controlled in accordance with the monitored emission intensity value. As a consequence, etching process operations having less resist damage can be continuously realized irrespective of a total number of wafers to be processed.

### Embodiment 1

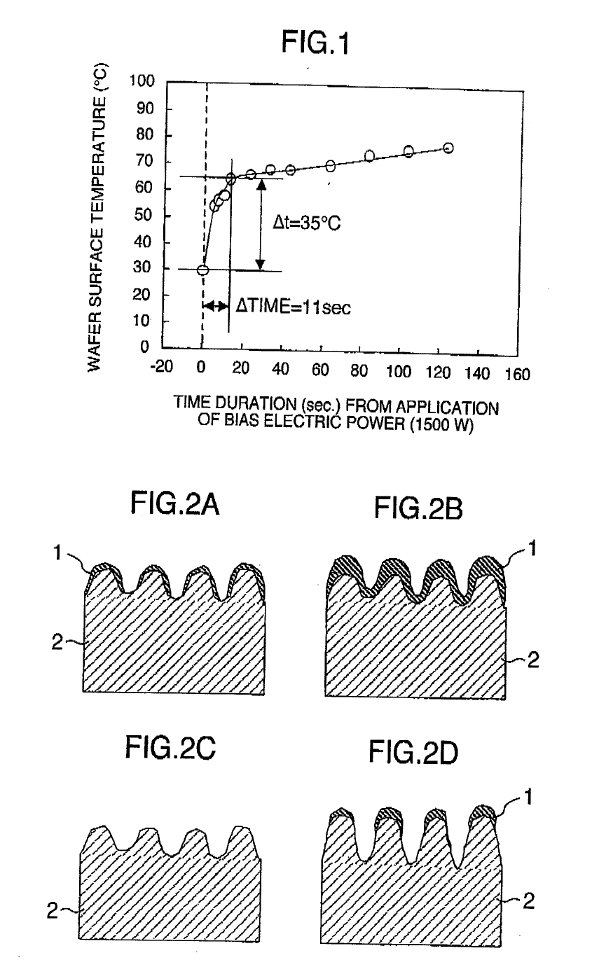

In Embodiment 1 of the present invention, an explanation is made of a method capable of reducing striation which is caused by resist damage by changing both timing defined after plasma is ignited until bias electric power is turned ON, and timing for conducting helium of a wafer back-side. FIG. 1 graphically represents a relationship between a time duration defined after bias electric power has applied to a wafer, which has been measured when a contact is processed, and a surface temperature of the wafer. It should be noted that a size of the wafer is 8 inches, and a setting value of the bias electric power is 1500 W. As represented in this drawing, under such an etching condition that bias electric power is relatively high, a surface temperature of the wafer is mainly determined by bias electric power. Under this etching condition, the following fact can be seen. That is, the surface temperature of the wafer is higher than a surface temperature thereof before the bias electric power is applied by approximately 35° C. Also, since an electrode on which the wafer is installed owns a heat capacity, a time duration of about 10 seconds is required until the temperature of the electrode is saturated. Under this contact processing condition, in order to secure a etching-selectivity with respect to a resist, such a mixed gas as Ar gas, C₄F₆ gas, O₂ gas, and CO gas is employed as etching gas. In this case, there are some possibilities that excessive depositions are made on the surface of the wafer until the temperature of the electrode is saturated.

FIG. 2A to FIG. 2D are schematic diagrams for explaining such cases that a surface of a resist 2 has been enlarged during etching process operation. FIG. 2A schematically shows such a case that a fluorocarbon deposited film 1 is less, and FIG. 2B schematically represents such a case that a fluorocarbon deposited film 1 is excessive. Next, ions are entered, so that energy is given to the surface of FIG. 2A, or FIG. 2B, and thus, the etching process operation is progressed. In the case of FIG. 2A, since the thickness of the deposited film is proper, the energy owned by the ions is not so attenuated by the fluorocarbon deposited film 1, but is reached up to the surface of the resist 2 functioning as underlayer. As a consequence, as indicated in FIG. 2C, concave/convex portion of the surface of this resist 2 may maintain such a status substantially equal to that of FIG. 2A. On the other hand, in the case of FIG. 2B that the fluorocarbon deposited film 1 is excessive, since the energy of the ions is not so attenuated in concave portions, the etching process operation is progressed, so that this etching process operation may be progressed until a depth substantially equal to the depth of the concave portions shown in FIG. 2C, whereas since the thickness of the fluorocarbon deposited film 1 is thick in the convex portions, the energy of the ions cannot be sufficiently reached up to the surface of the resist 2, so that the etching process operation is not progressed. As a result, as shown in FIG. 2D, the degree of the concave/convex portions becomes high, as compared with that of FIG. 2B, so that resist damage is advanced. In other words, the excessive deposition may constitute a major factor of the resist damage. In this example, a description is made of such a result that etching sequences were changed so as to suppress the excessive depositions made in the initial stage of the etching process operation, and then, resist damage was evaluated. As to the gas conditions, Ar gas was selected to 500 ml/min; C₄F₆ gas was selected to 30 ml/min; O₂ gas was selected to 36 ml/min; and CO gas was selected to 200 ml/min. At this time, pressure of the gas was set to 2 Pa. High frequency electric power for generating plasma is selected to 400 W under this condition.

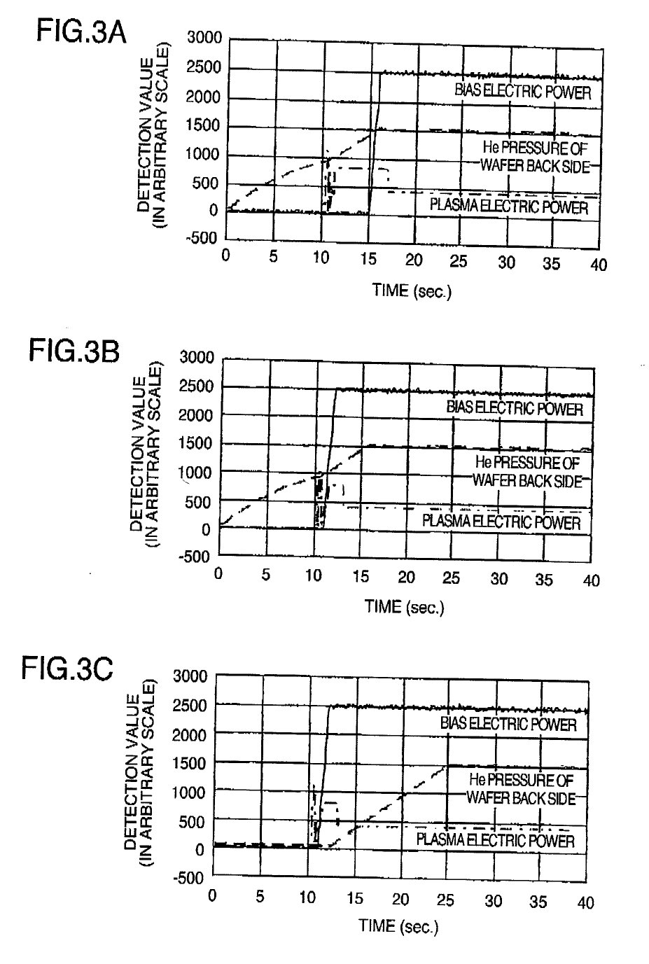

FIG. 3A, FIG. 3B, and FIG. 3C show 3 kinds of etching sequences under which evaluation has been carried out. These three etching sequences are assumed as a sequence “A”, a sequence “B”, and a sequence “C”, respectively. The sequence “A” corresponds to such an example that bias electric power is applied to a wafer after 5 seconds have elapsed since the plasma generating-purpose high frequency power supply was turned ON (namely, plasma has been ignited). In this case, while helium gas has been conducted between the wafer and an electrode before the plasma was ignited, pressure has been increased up to approximately 70 percents with respect to the set pressure (namely 1.5 KPa) at a time instant when the plasma is ignited. In this case, gas dissociated in the plasma becomes radicals of the CF series until the bias electric power is turned ON after the plasma has been ignited, and then, the radicals of the CF series are deposited on the wafer. In addition, since helium pressure of a back-side of the wafer has already become high, a temperature of this wafer is maintained at a low temperature, so that the deposition is emphasized. On the other hand, improved sequences are indicated in the etching sequences “B” and “C.” In the sequence “B”, bias electric power is applied to the wafer after 1 second has been elapsed since the plasma was ignited, and helium gas as to the back-side of the wafer is similar to that of the above-described sequence “A.” In the sequence “C”, bias electric power is applied to the wafer after 1 second has been elapsed since the plasma was ignited, and further, helium gas as to the back-side of the wafer is conducted at the same time when the bias electric power is applied to the wafer. As shown in FIG. 4, there is a close relationship between helium pressure of a back-side of a wafer and a surface temperature of the wafer, and the higher the helium pressure becomes, the lower the surface temperature becomes. A change ratio is nearly equal to 3.3° C./0.1 KPa under this experimental condition. As a consequence, it is conceivable that the temperature of the wafer becomes also high in the initial stage of the etching process operation in the sequence “C”, as compared with the wafer temperatures of the sequences “A” and “B.”

FIG. 5A to FIG. 5C represent scanning electron microscopy images (SEM images) which were acquired when an etching process operation was carried out in accordance with the above-explained 3 sequences.

A film structure corresponds to an ArF lithography-adaptive resist; an organic-film-series reflection preventing film (BARC) used to suppress forming of an abnormal pattern, which is caused by reflection/interference of laser; a silicon oxide film corresponding to a film to be processed; and a underlayer silicon substrate. In order to observe a longitudinal striation (striation 6) which has been formed in such a manner that resist image has been transferred to the silicon oxide film corresponding to the film to be processed, two layers of both the resist and BARC have been removed in an ashing process operation from a sample which has been etching-processed. In the case shown in FIG. 5A where the etching sequence “A” has been applied, there are seen a larger number of striations around dense hole pattern 4 and a phenomena that holes are made in places where patterns are not present (pitting 5), and a line edge roughness was 18.1 nm. This line edge roughness corresponds to an index as to a collapsing degree of a trench pattern 3. In contrast thereto, in such a case shown in FIG. 5B where the etching sequence “B” has been applied, both striation 6 and pitting 5 have been slightly improved, and also, a line edge roughness of a trench pattern 3 could been improved by 13.1 nm. Furthermore, in such a case shown in FIG. 5C where the etching sequence “C” has been applied, both striation 6 and pitting 5 have been improved, and also, a line edge roughness of a trench pattern 3 could been improved by 9.2 nm.

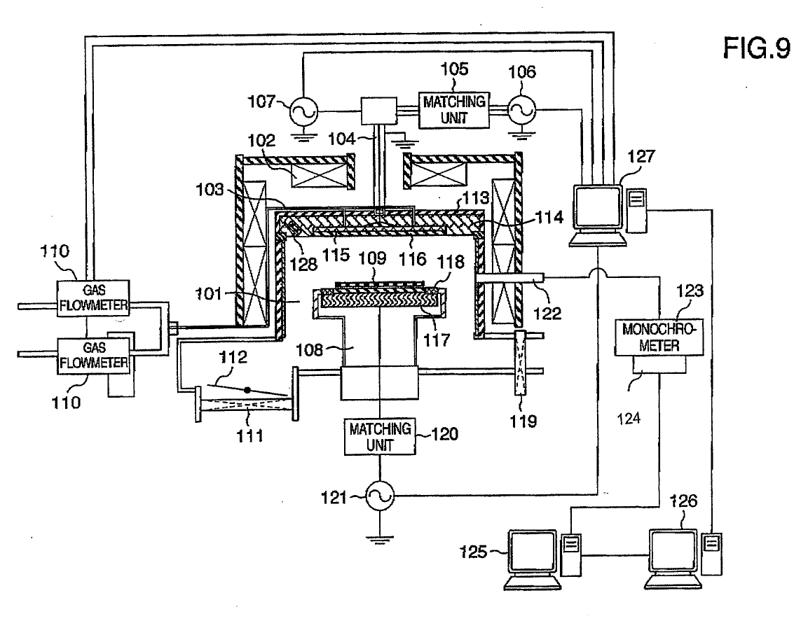

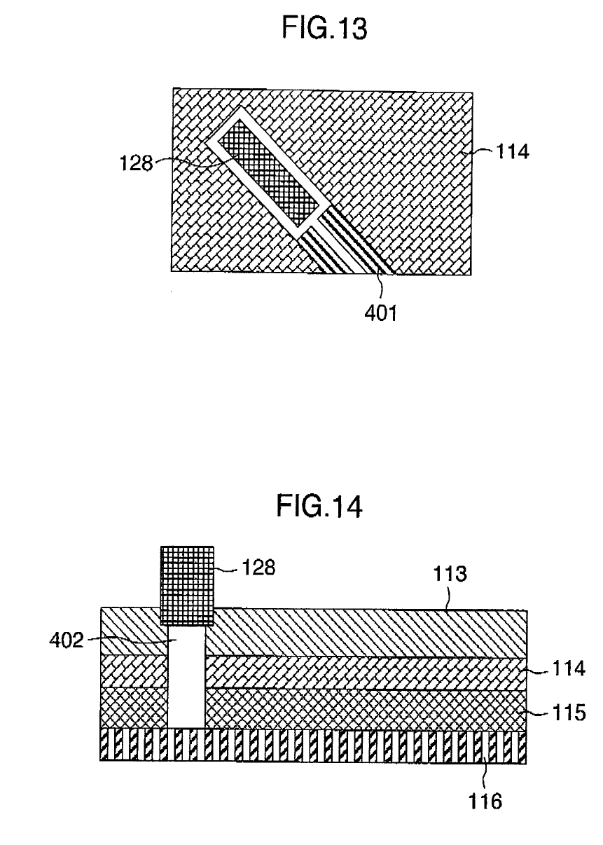

In the case that these process operations are carried out, a preliminary experiment may be alternatively performed in advance, and the helium pressure of the back-side of a wafer may be alternatively set in each of the process steps. Alternatively, while a surface temperature of the wafer may be continuously monitored by a radiation thermometer 128, it is also effective to control helium pressure of the back-side of a wafer in such a manner that this monitored temperature value may be equal to a desirable temperature value. The radiation thermometer 128 has been obliquely set within a dielectric member 114 which is located opposite to a wafer shown in FIG. 9. Alternatively, instead of monitoring a wafer surface temperature, a processing time dependent characteristic of the wafer surface temperature may be calculated based upon an etching condition, and then, the helium pressure of the back-side of a wafer may be set in either an automatic manner or a manual manner in such a way that this calculated processing time dependent characteristic may become a desirable profile. For instance, when the above-described radiation thermometer 128 is set, this radiation thermometer 128 may be preferably set to a deep place of a narrow tube 401 which is shown in an enlarged diagram of a radiation thermometer unit of FIG. 13. As a result, this setting condition of the radiation thermometer 128 can prevent fogs of this radiation thermometer unit, which are caused by depositions of fluorocarbon series produced in plasma. On the other hand, as represented in FIG. 14, another method may be alternatively conceived. That is, the radiation thermometer 128 may be set from a back-side of a silicon disk 16. In this alternative case, a quartz rod 402 may be preferably inserted so as to suppress abnormal discharging operations caused by electric fields.

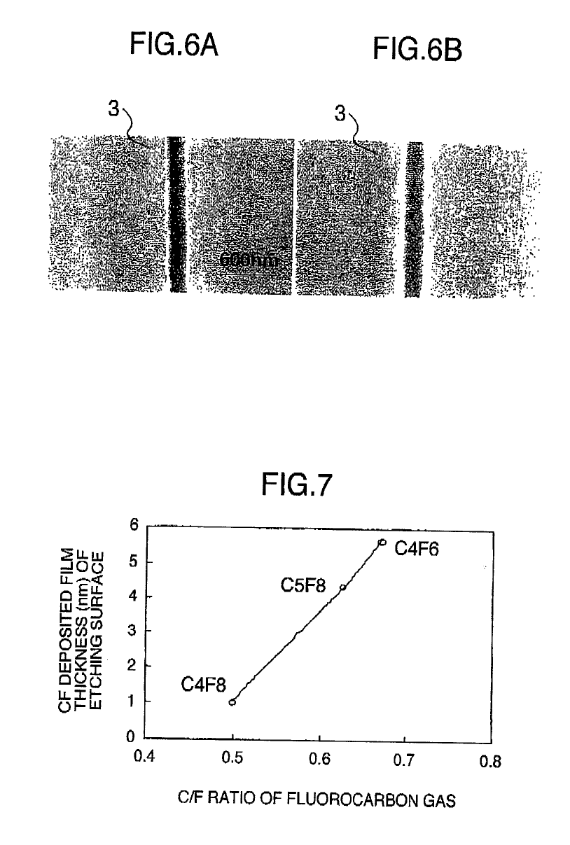

Next, a description is made of another embodiment executed in the case that a gas condition is changed in an initial stage of an etching operation. As the gas condition of the main etching operation, Ar gas was selected to 500 ml/min; C₄F₆ gas was selected to 30 ml/min; O₂ gas was selected to 36 ml/min; and CO gas was selected to 200 ml/min; and then, processing pressure was set to 2 Pa. In order to suppress depositions made when an etching process operation was commenced where a wafer surface temperature was low, such a process step that the gas condition has been changed was inserted for 12 seconds before the main etching operation is carried out. As to the gas condition, Ar gas is selected to 125 ml/min; C₄F₆ gas is selected to 7.5 ml/min; O₂ gas is selected to 7 ml/min; and CO gas is selected to 50 ml/min; and then, processing pressure is 0.5 Pa. At this time, electric power for plasma generating was selected to 400 W which is similar to that of the main etching condition. Under this condition, a deposition amount may be reduced by 40%, as compared with that of the main etching condition. An etching result obtained before this condition is applied is represented in FIG. 6A, and an etching result obtained after this condition has been applied is indicated in FIG. 6B. The line edge roughness of the trench pattern 3 was reduced from 13.6 nm to 9.0 nm. In this case, such an example has been represented in which such a condition that both the flow rate and the pressure were changed without changing the gas kinds has been inserted when the etching process operation is commenced. Alternatively, even if the above-explained condition is inserted when the etching process operation is commenced while the gas kinds are changed, another effect may be achieved. FIG. 7 graphically shows a relationship between a C/F ratio of CₓF_{y} gas and a CF deposition amount deposited on an etched surface. As apparent from this effect, even when the gas kinds are set to a low C/F ratio, the deposition amount may be reduced. As apparent from the foregoing descriptions, since the ON timing of the bias electric power, the ON timing of the wafer back-side helium, and the gas condition are changed in combination with each other, the effects may be increased.

Also, in view of suppressing an excessive deposition, it is desirable to change the main etching condition into a low pressure and low flow rate condition. Concretely speaking, the below-mentioned conditions are desirable. That is, while the Ar flow rate is selected from 0 ml/min to 200 ml/min, the CₓF_{y} gas flow rate is defined within a range from 2% to 10% of the Ar flow rate, and further, the processing pressure is defined within an range from 0.1 Pa to 1.0 Pa.

### Embodiment 2

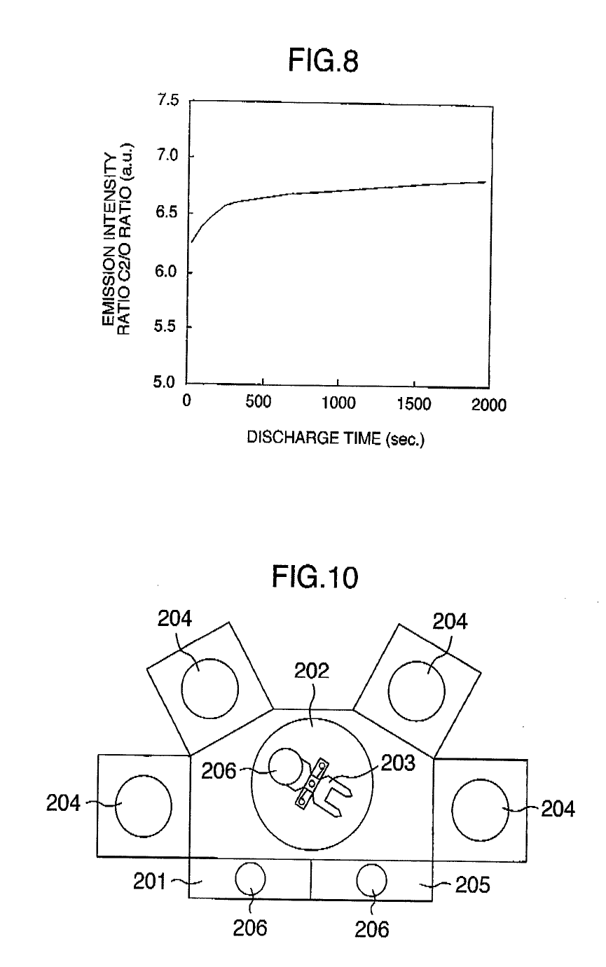

A description is made of Embodiment 2 according to the present invention, in which while an amount of radicals contained in plasma is monitored, a deposition suppressing step for an initial stage of an etching process operation is controlled. FIG. 8 represents such a result that plasma is ignited under condition that a wall of a vacuum chamber is cool, and then, an emission intensity ratio C₂/O ratio is monitored. In this monitoring result, an attention was paid to “C₂” as a radical seed of a carbon-series deposition, and also, paid to “O” as a radical seed for removing a deposited seed. The following fact can be understood. That is, up to approximately 200 seconds after a discharging operation was commenced, since the wall of the vacuum chamber is cool, the radicals contained in the plasma are absorbed to the wall, so that a smaller emission intensity ratio value than the original emission intensity ratio value is represented. After 200 seconds, the absorption of the radicals to the wall are balanced with the separations of the radicals from the wall, so that the emission intensity ratio C₂/O ratio is gradually increased, although the emission intensity ratio C₂/O ratio represents a saturation trend. In other words, the following fact is indicated. That is, in the case that etching process operations are carried out under the same condition in a mass production field, if a total number of processed wafers is increased, then deposited amounts in initial stages of etching process operations are increased. As previously explained in Embodiment 1, since the deposited amounts in the initial stages of the etching process operations are controlled, damage given to ArF lithography adaptable resists may be reduced. However, it is very important how to maintain etching performance under stable condition from a first wafer up to an “N”-th wafer in the mass production field.

FIG. 9 is a schematic diagram of an etching apparatus employed so as to realize Embodiment 2. Although an arrangement of this etching apparatus is not so largely different from the arrangement of the normal etching apparatus, this etching apparatus is equipped with a light emission/spectral measuring system for monitoring light emission emitted from plasma. The light emission/spectral measuring system is constituted by an optical fiber 122, a monochrometer 123, a photomultiplier tube 124, and a measurement-purpose personal computer 125 which performs a data sampling operation. Alternatively, instead of the photomultiplier tube 124, a CCD camera may be employed, so that light having a plurality of wavelengths may be measured at the same time.

On the other hand, a database-purpose personal computer 126 is provided between a control-purpose personal computer 127 for controlling an etching condition and the measurement-purpose personal computer 125. The database-purpose personal computer 126 instructs to automatically change the etching condition based upon a measurement value outputted from the measurement-purpose personal computer 125. Etching conditions (namely, ON timing of bias electric power, ON timing of wafer back-side helium, and gas conditions) for initial stages of etching process operations have been previously stored in the database with respect to either emission intensity or emission intensity ratios, which constitute subjects. It should be understood that this control instruction may be alternatively produced by previously acquiring a regular characteristic by way of an experiment, or may be alternatively and automatically produced by way of a simulation. Next, concrete flow process operations will be indicated. That is, a process operation of a first wafer is commenced. In this case, as the etching condition of the initial stage of the etching process operation, a predetermined condition is applied. While emission of plasma is continuously monitored by the light emission/spectral measuring system, both an emission intensity ratio (R1_1) and another emission intensity ratio (R1_2) are monitored. The emission intensity ratio (R1_1) is acquired at a predetermined time “t1” after the process operation has been entered into the steps of the main etching process operation, whereas the emission intensity ratio (R1_2) is acquired at a preselected time “t2” near the completion of the steps of the main etching process operation. Also, both emission intensity ratios (R2_1 and R2_2) acquired at the times “t1” and “t2” are monitored from a second wafer which has been processed under a similar condition to that of the first wafer. Based upon a comparison result of these 4 data, an emission intensity ratio “R3_1” is predicted so as to determine an etching condition which is employed in a step for an initial stage of an etching process operation. In this concrete flow-operation, such a method has been described in which emission data of a wafer which will be subsequently processed is predicted based upon emission data acquired up to the preceding wafer, and thus, a process condition is determined. Alternatively, a similar effect may be achieved by such a method that a process condition is changed in real time based upon emission data acquired at a time instant when an etching process operation is actually commenced. It should also be understood that this embodiment 2 is originally intended to control the etching condition within such a time range that the wafer temperature in the initial stage of the etching process operation is brought into a transient state, but is not intended to change the main etching condition.

In the above-described etching apparatus of FIG. 9, reference numeral 101 shows a vacuum chamber; reference numeral 102 represents an air-core coil; reference numeral 103 indicates a gas introducing tube; reference numeral 104 denotes a coaxial line; reference numeral 105 shows a matching unit; reference numeral 106 indicates a 450-MHz power supply; reference numeral 107 represents a 13.56-MHz power supply; reference numeral 108 shows a lower electrode; reference numeral 109 represents a sample to be processed; reference numeral 110 shows a gas flow meter; reference numeral 111 denotes a main valve; reference numeral 112 represents a conductance valve; reference numeral 113 shows an earth potential conductor plate; reference numeral 117 indicates an electrostatic chuck unit; reference numeral 118 indicates a focus ring; and reference numeral 119 represents a gate valve.

### Embodiment 3

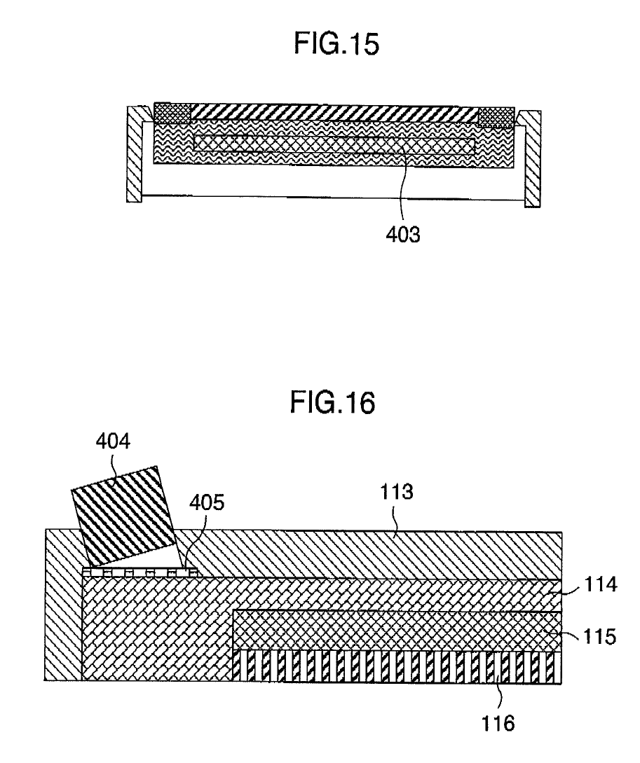

In Embodiment 3 of the present invention, a description is made of such an embodiment that a temperature of a wafer is increased before a process operation is carried out, while a process condition is not changed. FIG. 10 is a diagram for schematically showing an etching system. In this etching system, after a wafer 206 has been derived from a cassette, this wafer 206 is transported via a step for executing an alignment control to a load lock chamber 201 where air is sucked in a vacuum sucking manner. Thereafter, the wafer 206 is conducted via a buffer chamber 202 into an etching chamber 204. After a predetermined process operation is carried out in the etching chamber 204, the wafer 206 is transported from an unload lock chamber 205 outside the apparatus. Embodiment 3 has described such an example that the alignment control is carried out in an atmospheric condition. Alternatively, this alignment control may be carried out in a vacuum condition. Embodiment 3 is featured by that the wafer 206 has been previously preheated. As a preheating means, for instance, a heater may be preferably set to an arm 203 of a vacuum transport-purpose robot in the buffer chamber 202. It should be noted that although not shown in this drawing, a control apparatus has been installed on the heater set to the arm 203 of the robot in the buffer chamber 202, while this control apparatus controls a temperature of the heater to a set temperature. Alternatively, the above-described control apparatus may be connected to the database-purpose personal computer 126 shown in FIG. 9 via a signal transfer line so as to transfer an optimum setting temperature signal from the database-purpose personal computer 126 to the buffer chamber 202. Also, as another preheating method, even after the wafer 206 has been transported to the etching chamber 204, this wafer 206 may be alternatively preheated. In this alternative case, as represented in FIG. 15, a temperature of the wafer 206 is increased to a predetermined temperature by employing a heater 403 embedded in an electrode before a process operation is carried out, and thereafter, this process operation is commenced. On the other hand, it is also effective that the wafer 206 may be alternatively heated by using a lamp 404 via a dielectric member 114 which is typically realized by quartz (shown in FIG. 16) outside the etching chamber 204. In this alternative case, it is desirable to set a punch metal 405 in order to prevent leakage of electromagnetic waves. This punch metal 405 is made by piercing holes in a conductor plate.

An increased temperature “ΔT” as to a surface temperature “T” of a wafer under steady-state etching condition may be determined based upon the following equation: ΔT=QxR1+QxR2+QxR3 when entered heat “Q” caused by bias electric power which is applied to the wafer 206, and thermal resistances (wafer R1, wafer back-side helium R2, and electrode R3) are employed. As a result, the increased temperature “ΔT” may be exclusively determined with respect to the bias electric power, and the wafer surface temperature “T” under the steady-state etching condition may be expressed as T=T1+ΔT by employing a temperature “T1” of refrigerant flowing through the electrode. As a consequence, if the wafer 206 is heated up to at least such a temperature substantially equal to the wafer surface temperature “T” which is predicted under the steady-state etching condition, then the low temperature condition in the initial stage of an etching process operation may be avoided. Also, while considering such a fact that the temperature of the wafer 206 is lowered by setting this wafer 206, a preheating temperature is controlled to become higher than the wafer surface temperature “T”, which may achieve an effect capable of avoiding the low temperature condition in the initial stage of the etching process operation. This reason is given as follows. That is, when the wafer 206 is set on the electrode, since the temperature of the electrode is low, there are some possibilities that the temperature of the wafer 206 is lowered. Alternatively, an etching process operation may be commenced at the same time when the wafer 206 is set on the electrode, or at a stage as soon as possible when the wafer 206 is set on the electrode. To this end, timing for starting the etching process operation may be alternatively controlled under such a condition that the setting timing of the wafer 206 is defined as a reference.

### Embodiment 4

In Embodiment 4 of the present invention, a description is made of methods for manufacturing semiconductor devices which own the below-mentioned features.

That is, such a manufacturing method of a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; a step for etching the organic-film-series reflection preventing film while the resist pattern is employed as a mask; and a step for detecting an ignition of plasma; in which a layer to be processed is etched while both a remaining film of the resist pattern and the organic-film-series reflection preventing film are employed as a mask; and when the etching process operation as to both the organic-film-series reflection preventing film and the layer to be processed is commenced, a time duration defined after the plasma has been ignited until bias electric power is applied to the semiconductor substrate is controlled in correspondence with the plasma ignition detected value.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; and a step for etching the organic-film-series reflection preventing film while the resist pattern is employed as a mask; in which a layer to be processed is etched while both a remaining film of the resist pattern and the organic-film-series reflection preventing film are employed as a mask; and when the etching process operation as to both the organic-film-series reflection preventing film and the layer to be processed is commenced, bias electric power is applied to the semiconductor substrate before the plasma is brought into a steady-state condition.

Further, such a method for manufacturing a semiconductor device may be provided. That is, in the above-explained semiconductor device, the time duration after the plasma has been ignited until the bias electric power is applied to the semiconductor substrate is set to be within 1 second.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; and a step for etching the organic-film-series reflection preventing film while the resist pattern is employed as a mask; in which a layer to be processed is etched while both a remaining film of the resist pattern and the organic-film-series reflection preventing film are employed as a mask; and when the etching process operation as to both the organic-film-series reflection preventing film and the layer to be processed is carried out, a time duration after the etching process operation has been commenced until a temperature of the semiconductor substrate is saturated to a constant value is changed into such a gas condition that a deposition amount on the semiconductor substrate becomes smaller than that of the etching condition, and then, the etching process operation is carried out.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; a step for etching the organic-film-series reflection preventing film while the resist pattern is employed as a mask; and a step for detecting an ignition of plasma; in which a layer to be processed is etched while both a remaining film of the resist pattern and the organic-film-series reflection preventing film are employed as a mask; when the etching process operation as to both the organic-film-series reflection preventing film and the layer to be processed is commenced, a time duration defined after the plasma has been ignited until bias electric power is applied to the semiconductor substrate is controlled in correspondence with the plasma ignition detected value; and a time duration after the etching process operation has been commenced until a temperature of the semiconductor substrate is saturated to a constant value is changed into such a gas condition that a deposition amount on the semiconductor substrate becomes smaller than that of the etching condition, and then, the etching process operation is carried out in combination with the above-described control operation.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; and a step for etching the organic-film-series reflection preventing film while the resist pattern is employed as a mask; in which a layer to be processed is etched while both a remaining film of the resist pattern and the organic-film-series reflection preventing film are employed as a mask; when the etching process operation as to both the organic-film-series reflection preventing film and the layer to be processed is carried out, bias electric power is applied to the semiconductor substrate before the plasma is brought into a steady-state condition; and also, a time duration defined after the etching process operation has been commenced until a temperature of the semiconductor substrate is saturated to a constant value is changed into such a gas condition that a deposition amount on the semiconductor substrate becomes smaller than that of the etching condition, and then, the etching process operation is carried out in combination with the application of the bias electric power.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; and a step for etching the organic-film-series reflection preventing film while the resist pattern is employed as a mask; in which a layer to be processed is etched while both a remaining film of the resist pattern and the organic-film-series reflection preventing film are employed as a mask; and a further step is conducted to the semiconductor device manufacturing method, in which when both the organic-film-series reflection preventing film and the layer to be processed are etched, the etching process operation is carried out by setting pressure of gas which is filled between the semiconductor substrate and an electrode used to set thereon the semiconductor substrate to such a pressure which is lower than predetermined pressure under main etching condition.

Alternatively, according to Embodiment 4, another method for manufacturing a semiconductor device may be provided. The semiconductor device manufacturing method is comprised of: a step for forming a predetermined thin film on a semiconductor substrate; a step for forming an organic-film-series reflection preventing layer on the thin film; a step for forming a resist pattern on the organic-film-series reflection preventing layer, the resist pattern having C═O coupling under such a condition that a weight ratio of a benzene ring is smaller than, or equal to 20%; and a step for etching the organic-film-series reflection preventing film while the resist pattern is employed as a mask; in which a layer to be processed is etched while both a remaining film of the resist pattern and the organic-film-series reflection preventing film are employed as a mask; a further step is conducted to the semiconductor device manufacturing method in which when both the organic-film-series reflection preventing film and the layer to be processed are etched, the etching process operation is carried out by setting pressure of gas which is filled between the semiconductor substrate and an electrode used to set thereon the semiconductor substrate to such a pressure which is lower than predetermined pressure under main etching condition; and the processing time is controlled in accordance with a temperature of the semiconductor substrate.

Alternatively, the following method for manufacturing a semiconductor device may be provided. That is, in the above-described 6 manufacturing methods of the semiconductor devices, a further step is conducted to the semiconductor device manufacturing methods, in which when both the organic-film-series reflection preventing film and the layer to be processed are etched, the etching process operation is carried out by setting pressure of gas which is filled between the semiconductor substrate and an electrode used to set thereon the semiconductor substrate to such a pressure which is lower than predetermined pressure under main etching condition.

Alternatively, the following method for manufacturing a semiconductor device may be provided. That is, in the above-described 6 manufacturing methods of the semiconductor devices, a further step is conducted to the semiconductor device manufacturing methods, in which when both the organic-film-series reflection preventing film and the layer to be processed are etched, the etching process operation is carried out by setting pressure of gas which is filled between the semiconductor substrate and an electrode used to set thereon the semiconductor substrate to such a pressure which is lower than predetermined pressure under main etching condition; and the above-described time is controlled in accordance with a temperature of the semiconductor substrate.

Alternatively, a semiconductor device manufacturing method may be provided which is comprised of a step in which a gas condition of a time duration after an etching process operation has been commenced until a temperature of a semiconductor substrate is saturated to a constant value is carried out by way of gas having a lower C/F ratio than that of a main etching condition.

Alternatively, a semiconductor device manufacturing method may be provided which is comprised of a step in which a gas condition of a time duration after an etching process operation has been commenced until a temperature of a semiconductor substrate is saturated to a constant value is to apply CₓF_{y} gas having a lower flow rate than that of a main etching condition.

Alternatively, a semiconductor device manufacturing method may be provided which is comprised of a step for measuring a radical amount contained in plasma, and in which a time duration after the plasma has been ignited until bias electric power is applied to a semiconductor substrate is controlled in accordance with a variation of the radical amount.

Alternatively, a semiconductor device manufacturing method may be provided which is comprised of a step for measuring a radical amount contained in plasma, and in which a gas condition of a time duration after the plasma has been ignited until bias electric power is applied to a semiconductor substrate is changed in accordance with a variation of the radical amount.

Further, a semiconductor device manufacturing method may be alternatively provided which is comprised of a step for setting bias electric power of a wafer in an initial stage of an etching process operation to be higher than that of a main etching condition.

### Embodiment 5

In Embodiment 5 of the present invention, a description is made of such an etching method capable of improving process performance by switching pressure as to helium gas of a back-side of a wafer during a process operation, while the helium gas is conducted between the wafer and an electrode. As to pattern structures which may constitute a subject pattern structure, if these pattern structures own etching stop films, then any kind of pattern structures may be employed. Although this embodiment 5 will describe such an example that a high aspect ratio contact is processed, it is obvious that even when this inventive idea is applied to a Via process operation in a damascene structure with employment of an Low-k film, an effect may be similarly achieved. As shown in FIG. 4, there is a correlative relationship between pressure as to helium gas of a back-side of a wafer and a temperature of a wafer. In particular, in such an etching process operation whose bias electric power is high, even when a temperature of refrigerant is changed, a lengthy time is required so as to change a surface temperature of a wafer. In contrast, since the control of the above-described helium pressure of the back-side of a wafer largely causes rate-controlling of a heat conduction, this helium pressure control may become very effective with respect to a high-speed change in the surface temperatures of the wafer.

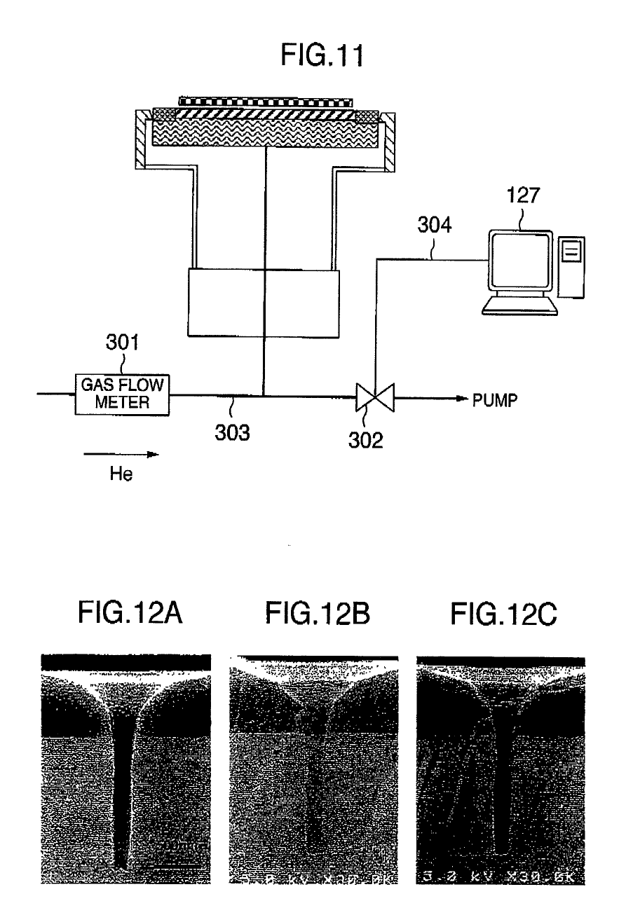

A film structure which constitutes a subject structure is ArF resist /BARC/TEOS/Si₃N₄. First, after a BARC process operation has been carried out, an etching process operation is executed under main etching condition. As to gas conditions of the main etching operation, Ar gas was selected to be 500 ml/min; C₄F₆ gas was selected to be 30 ml/min; O₂ gas was selected to be 34 ml/min; and CO gas was selected to be 200 ml/min, and then, processing pressure was set to 2 Pa. High frequency electric power for plasma generation is 400 W, and bias electric power of the wafer is 1500 W under the present condition. In this case, in order to suppress etching damage of an ArF resist which functions as a mask, pressure as to the back-side of the wafer was selected to be 1.5 KPa. Under this condition, TEOS was etched, and then, when the remaining film became 50 nm, the helium pressure of wafer back-side was lowered from 1.5 KPa up to predetermined pressure so as to perform an over etching operation. One condition corresponds to 1.0 KPa, and another condition corresponds to 0.7 KPa. In this embodiment 5, an evaluation was carried out by employing such an electrode structure shown in FIG. 11. This electrode is equipped with a gas pipe 303 through which helium gas flows, a valve 302 for controlling back-side pressure, a transmission path, and also, a gas flowmeter for helium 301. This back-side pressure control valve 302 is used so as to control pressure as to helium gas of the back-side of wafer. The transmission path is employed so as to transmit a valve opening/closing control signal 304 supplied from the control-purpose personal computer 127, while this valve opening/closing control signal 304 is used to drive the valve 302 for the wafer back-side pressure control. While pressure within the gas pipe 303 is measured by a pressure gauge (not shown), as explained above, in the case that the wafer back-side helium pressure is lowered after a certain etching time has elapsed, the valve 302 for the wafer back-side pressure control is opened in response to the valve opening/closing control signal. In Embodiment 5, a pressure control operation is carried out in accordance with the below-mentioned control manner. That is, although the wafer back-side helium pressure is instantaneously lowered, a value of the pressure gauge is compared with a set pressure value, and in such a case that a pressure value is lower than the set pressure value, the wafer back-side pressure control valve 302 is closed in response to the valve opening/closing control signal 304, and the pressure control operation is carried out by using the gas flowmeter 301 for helium in such a manner that the lowered gas pressure value becomes equal to the set pressure value. Under the condition of Embodiment 5, a time duration required to switch the wafer back-side helium pressure was 1.5 seconds. Also, since the wafer back-side helium pressure was changed from 1.5 KPa to 1.0 KPa, the surface temperature of the wafer was increased to 12° C., and since the wafer back-side helium pressure was changed from 1.5 KPa to 0.7 KPa, the surface temperature of the wafer was increased to 23° C. FIG. 12A to FIG. 12C are images of scanning electron microscopy which represent etching shapes. FIG. 12A shows an etching shape in the case that the wafer back-side helium pressure is not changed. FIG. 12B indicates an etching shape in the case that the wafer back-side helium pressure was changed to 1.0 KPa during an over etching operation. FIG. 12C represents an etching shape in the case that the wafer back-side helium pressure was changed to 0.7 KPa during an over etching operation. As a result of these experiments, in such a case that the wafer back-side helium pressure was no changed, the underlayer Si₃N₄ film was punched through, whereas in the case that the wafer back-side helium pressure was lowered during the over etching operation, the underlayer selectivity was improved and the punching through phenomenon of the underlayer Si₃N₄ film was suppressed. However, in such a case that the wafer back-side helium pressure was lowered up to 0.7 KPa, damage was produced in a resist facet portion. In this experiment, in the case that the wafer back-side helium pressure was changed from 1.5 KPa to 1.0 KPa, compatibility between the resist damage and the improvement in the underlayer selectivity could be achieved. This reason may be conceived as follows: That is, since the surface temperature of the wafer is increased, reactions occurred on the resist surface are progressed in either a chemical manner or a physical manner. On the other hand, this reason may be also conceived. That is, since the surface temperature of the wafer is increased, a sticking coefficient of depositions is effectively lowered and the depositions are transported deep into holes, so that the underlayer selectivity could be improved. As a consequence, as apparent from the foregoing descriptions, the pressure value as to the helium gas of the back-side of the wafer must be set to such an optimum value by which the compatibility between the resist damage and the improvement in the underlayer selectivity can be established.

It should be further understood by those skilled in the art that although the foregoing description has been made on embodiments of the invention, the invention is not limited thereto and various changes and modifications may be made without departing from the spirit of the invention and the scope of the appended claims.

What we claim is:

1. A dry-etching method for use in an apparatus comprising a vacuum chamber which has been vacuum-exhausted by vacuum exhausting means, gas conducting means for conducting etching gas into said vacuum chamber; means for setting a sample to be processed; and electric power conducting means for conducting high frequency electric power to said vacuum chamber, said etching gas conducted into said vacuum chamber by said gas conducting means being converted into plasma by using the high frequency electric power conducted by said electric power conducting means, and a surface of said sample to be processed being processed using said plasma;
said dry-etching method comprising:
detecting an ignition of the plasma;
measuring an amount of radicals contained in the plasma;
applying bias electric power to said sample to be processed;
and
controlling a starting time for applying said bias electric power;
wherein said step of controlling includes pre-storing information representing a relationship between amounts of radicals contained in the plasma and starting times of applying said bias electric power to the sample in a database;
wherein, when the surface processing operation of said sample to be processed is commenced, said step of controlling further includes:
receiving an indication of the ignition of the plasma from the detecting means;
reading the amount of radicals contained in the plasma from the measuring means;
comparing the read amount of radicals with the database to determine a first time duration between a time when the plasma is ignited to a time to start applying said bias electric power, which first time duration corresponds, in the database, to the read amount of radical contained in the plasma measured by the measuring means; and
starting the application of the bias electric power to the sample at the end of the first time duration following the ignition of the plasma.

2. A dry-etching method using a plasma processing apparatus which includes a vacuum chamber evacuated by a vacuum pump means, a gas conducting means for conducting an etching gas into said vacuum chamber, means for conducting an etching gas into said vacuum chamber, means for disposing a sample to be processed, and electric power conducting means for conducting high frequency electric power into said vacuum chamber, a gas conducted into said vacuum chamber from said gas conducting means being converted into plasma by using the high frequency electric power conducted by said electric power conducting means, and a surface of the sample to be processed being processed using said plasma;
said method etching said sample to be processed having a layer structure comprising a silicon oxide film formed on a base silicon substrate as a film to be processed, an organic-film-series reflection preventing film formed on said silicon oxide film, and an ArF resist pattern formed on said organic-system reflection preventing film, said method comprising:
a step of etching said organic-film-series reflection preventing film using said ArF resist pattern as a mask;
a step of etching said silicon oxide film using a film remaining from said ArF resist pattern and said organic-system reflection preventing film as a mask;
a step of detecting ignition of plasma for said etching;
a step of applying bias electric power to said sample to be processed; and
a step of controlling a starting time for applying said bias electric power to start the bias electric power at a time subsequent to the ignition of the plasma by performing one of the following steps:
(1) when starting the etching of said silicon oxide film to be processed, controlling a time duration between a time when the plasma is ignited to a time to start applying said bias electric power to the substrate based on a detected value of said plasma ignition; or
(2) controlling said time duration to be one second or less.

3. A dry-etching method using a plasma processing apparatus which includes a vacuum chamber evacuated by a vacuum pump means, a gas conducting means for conducting an etching gas into said vacuum chamber, means for disposing a sample to be processed, and electric power conducting means for conducting high frequency electric power into said vacuum chamber, a gas conducted into said vacuum chamber from said gas conducting means being converted into plasma by using the high frequency electric power conducted by said electric power conducting means, and a surface of the sample to be processed being processed using said plasma;
said method etching said sample to be processed having a layer structure comprising a silicon oxide film formed on a base silicon substrate as a film to be processed, an organic-film-series reflection preventing film formed on said silicon oxide film, and a ArF resist pattern formed on said organic-system reflection preventing film, said method comprising:
a step of etching said organic-film-series reflection preventing film using said ArF resist pattern as a mask;
a step of etching said silicon oxide film using a film remaining from said ArF resist pattern and said organic-system reflection preventing film as a mask;
a step of detecting ignition of plasma for said etching;
a step of applying bias electric power to said sample to be processed;
a step of controlling a starting time for applying said bias electric power;
a step of measuring an amount of radicals contained in the plasma; and
when starting the etching of said silicon oxide film to be processed, controlling at least one of a timing for applying the bias electric power, a gas condition at an initial stage of an etching process operation and a substrate back-side gas pressure based on the measured radical amount.
